(19) United States
(12) Patent Application Publication
(10) Pub. No.: US 2023/0266943 A1
(43) Pub. Date: Aug. 24, 2023

(54) DIGITAL IN-MEMORY COMPUTING MACRO BASED ON APPROXIMATE ARITHMETIC HARDWARE

(71) Applicant: The Trustees of Columbia University in the City of New York, New York, NY (US)

(72) Inventors: Mingoo Seok, Tenafly, NJ (US); Dewei Wang, New York, NY (US); Chuan-Tung Lin, New York, NY (US)

(21) Appl. No.: 18/110,152

(22) Filed: Feb. 15, 2023

Related U.S. Application Data
(60) Provisional application No. 63/311,787, filed on Feb. 18, 2022.

(51) Int. Cl. G06F 7/544; G06F 7/53; G06F 7/501; H03K 19/20

(52) U.S. Cl. CPC G06F 7/5443; G06F 7/5312; G06F 7/501; H03K 19/20

(57) ABSTRACT

Various embodiments described herein provide for a digital In-Memory Computing (IMC) macro circuit that utilizes approximate arithmetic hardware to reduce the number of transistors and devices in the circuit relative to a convention digital IMC, thereby improving the area-efficiency of the digital IMC, but while retaining the benefits of reduced variability relative to an analog-mixed-signal (AMS) circuit. The proposed digital IMC macro circuit also includes custom full adder (FA) circuits with pass gate logic in a ripple carry adder (RCA) tree. The disclosed digital IMC macro circuit can also perform a vector-matrix dot product in one cycle while achieving high energy and area efficiency.

### RELATED APPLICATIONS

This application claims the benefit of provisional patent application Ser. No. 63/311,787, filed Feb. 18, 2022, the disclosure of which is hereby incorporated herein by reference in its entirety.

### GOVERNMENT SUPPORT

This invention was made with government support under grant number 1919147 awarded by the National Science Foundation. The Government has certain rights in this invention.

### FIELD OF THE DISCLOSURE

The present disclosure relates to a digital in-memory computing macro circuit, and in particular to implementing a digital in-memory computing macro circuit with approximate arithmetic hardware.

### BACKGROUND

In-memory computing (IMC) is a computing architecture that leverages the use of memory storage instead of Von-Neumann architecture storage for data processing. IMC involves storing data in high-speed memory chips and performing processing on it directly, rather than moving the data back and forth from conventional on-chip memory (e.g., static random-access memory “SRAM”) to processing units. Convention SRAM can only be accessed row-by-row or one row at a time while IMC SRAM can access the data across all rows, enabling higher throughput and energy efficiency. This results in much faster processing times compared to traditional disk-based computing.

IMC SRAM architecture achieves very high energy efficiency for computing a convolutional neural network (CNN) model, which is widely used in artificial intelligent (AI) devices. A major issue of the current IMC SRAMs is that due to the use of analog-mixed-signal (AMS) hardware for high area- and energy-efficiency, process, voltage, and temperature (PVT) variations limit the computing precision and inference accuracy of a CNN significantly. AMS computing hardware has a significant root-mean-square error (RMSE) of 22.5% across the worst-case voltage, temperature and 3-sigma process variations. An IMC SRAM macro can be implemented with robust digital logic which can eliminate that variability issue, but digital circuits require more devices, transistors, etc. than AMS counterparts. FIG. 1 depicts a conventional full adder circuit 100 that uses full adder circuits (e.g., 104-1, 104-2, 104-3, and etc.) to sum the input 120 from multiply-and-accumulate (MAC)-bitlines of the memory cell to create an output 106 (e.g., represented by output signals 106-1, 106-2, 106-3, and 106-4). As a result, an example digital IMC SRAM can have a much worse area efficiency and higher power usage than an AMS counterpart.

### SUMMARY

Various embodiments described herein provide for a digital In-Memory Computing (IMC) macro circuit that utilizes approximate arithmetic hardware to reduce the number of transistors and devices in the circuit relative to a convention digital IMC, thereby improving the area-efficiency of the digital IMC, but while retaining the benefits of reduced variability relative to an analog-mixed-signal (AMS) circuit. The proposed digital IMC macro circuit also includes custom full adder (FA) circuits with pass gate logic in a ripple carry adder (RCA) tree. The disclosed digital IMC macro circuit can also perform a vector-matrix dot product in one cycle while achieving high energy and area efficiency.

In an embodiment, a digital in-memory computing macro circuit can include a plurality of approximate compressors wherein each approximate compressor of the plurality of approximate compressors receives as an input a plurality of bitcell values of a plurality of bitcell multiplications and generates an output comprising an approximate sum of the plurality of bitcell values. The digital in-memory computing macro circuit can also include an adder tree that receives a plurality of approximate sums, the plurality of approximate sums comprising an approximate sum from each approximate compressor of the plurality of approximate compressors and generates a sum corresponding to a total value of the plurality of bitcell multiplications, wherein the adder tree comprises a plurality of ripple carry adders that each comprise a plurality of full adder circuits that use inverters such that the number of series-connected pass-gates in each full adder circuit of the plurality of full adder circuits is less than two. The digital in-memory computing macro circuit can also include a shift accumulator that accumulates the sum and sums of subsequent bitcell multiplication cycles in a pipeline.

In another embodiment, a digital in-memory computing macro circuit can include a plurality of single approximate compressors wherein each single approximate compressor of the plurality of approximate compressors receives as an input a plurality of bitcell values of a plurality of bitcell multiplications and generates an output comprising an approximate sum of the plurality of bitcell values. The digital in-memory computing macro circuit can also include an adder tree that receives a plurality of approximate sums, the plurality of approximate sums comprising an approximate sum from each single approximate compressor of the plurality of single approximate compressors and generates a sum corresponding to a total value of the plurality of bitcell multiplications, wherein the adder tree comprises a plurality of ripple carry adders that each comprise a plurality of full adder circuits that use inverters such that the number of series-connected pass-gates is less than two. The digital in-memory computing macro circuit can also include a shift accumulator that accumulates the sum and sums of subsequent bitcell multiplication cycles in a pipeline.

In another embodiment, a digital in-memory computing macro circuit can include a plurality of double approximate compressors wherein each double approximate compressor of the plurality of double approximate compressors receives as an input a plurality of bitcell values of a plurality of bitcell multiplications and generates an output comprising an approximate sum of the plurality of bitcell values. The digital in-memory computing macro circuit can also include an adder tree that receives a plurality of approximate sums, the plurality of approximate sums comprising an approximate sum from each double approximate compressor of the plurality of double approximate compressors and generates a sum corresponding to a total value of the plurality of bitcell multiplications, wherein the adder tree comprises a plurality of ripple carry adders that each comprise a plurality of full adder circuits that use inverters such that the number of series-connected pass-gates is less than two. The digital in-memory computing macro circuit can also include a shift accumulator that accumulates the sum and sums of subsequent bitcell multiplication cycles in a pipeline.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a diagram showing a conventional full adder circuit.

FIG. 2 is a diagram showing the digital in memory computing architecture according to one or more embodiments of the present disclosure.

FIG. 3 is a diagram showing a single approximate full adder circuit according to one or more embodiments of the present disclosure.

FIG. 4 is a diagram showing a double approximate full adder circuit according to one or more embodiments of the present disclosure.

FIG. 5 is a diagram showing a ripple carry adder tree according to one or more embodiments of the present disclosure.

FIG. 6 is a diagram showing a first type of custom full adder circuit using pass-gate logic according to one or more embodiments of the present disclosure.

FIG. 7 is a diagram showing a second type of custom full adder circuit using pass-gate logic according to one or more embodiments of the present disclosure.

FIG. 8 is a diagram showing a ripple carry adder including several custom full adder circuits according to one or more embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

In-memory computing (IMC) static random-access memory (SRAM) architecture has gained significant attention as it has achieved very high energy efficiency for computing a convolutional neural network (CNN) model. Recent works investigated the use of analog-mixed-signal (AMS) hardware for high area efficiency and energy efficiency. However, the output for AMS hardware is well known to vary across process, voltage, and temperature (PVT) variations, limiting the computing precision and ultimately the inference accuracy of a CNN. This was confirmed, through the simulation of a capacitor-based IMC SRAM macro that computes 256-d(imension) binary dot product, that the AMS computing hardware has a significant root-mean-square error (RMSE) of 22.5% across the worst-case voltage, temperature, and 3-sigma process variations. On the other hand, an IMC SRAM macro using robust digital logic can be implemented that can virtually eliminate the variability issue. However, as described in the background, digital circuits require more devices than AMS counterparts, for example, 28 transistors for a mirror full adder (FA). As a result, a recent digital IMC SRAM shows a worse area efficiency of 6368 F²/b (22 nm, 4b/4b weight/activation) than the AMS counterpart (1170 F²/b, 65 nm, 1b/1b).

Various embodiments described herein provide for a digital IMC macro circuit that utilizes approximate arithmetic hardware to reduce the number of transistors and devices in the circuit relative to a convention digital IMC, thereby improving the area-efficiency of the digital IMC, but while retaining the benefits of reduced variability relative to an AMS circuit. The proposed digital IMC macro circuit also includes custom FA circuits with pass gate logic in a ripple carry adder (RCA) tree. The disclosed digital IMC macro circuit can also perform a vector-matrix dot product in one cycle while achieving high energy and area efficiency

In light of this, the present disclosure relates to approximate arithmetic hardware to improve area and power efficiency and to two digital IMC (DIMC) macros with different levels of approximation. The first DIMC macro uses a single approximate arithmetic compressor in place of a fully digital compressor. The second DIMC macro uses a variation of the first DIMC macro that instead uses a double approximate arithmetic compressor. Also, the present disclosure relates to an approximation-aware training algorithm and a number format to minimize inference accuracy degradation induced by approximate hardware. A 28-nm test chip was used as a prototype: for a 1b/1b CNN model for CIFAR-10 and across 0.5 V to 1.1 V supply, the DIMC with double-approximate hardware (DIMC-D) achieves 2569 F²/b, 932-2219 TOPS/W, 475-20032 GOPS, and 86.96% accuracy, whereas for a 4b/1b CNN model, the DIMC with the single-approximate hardware (DIMC-S) achieves 3814 F²/b, 458-990 TOPS/W (normalized to 1b/1b), 405-19215 GOPS (normalized to 1b/1b), and 90.41% accuracy.

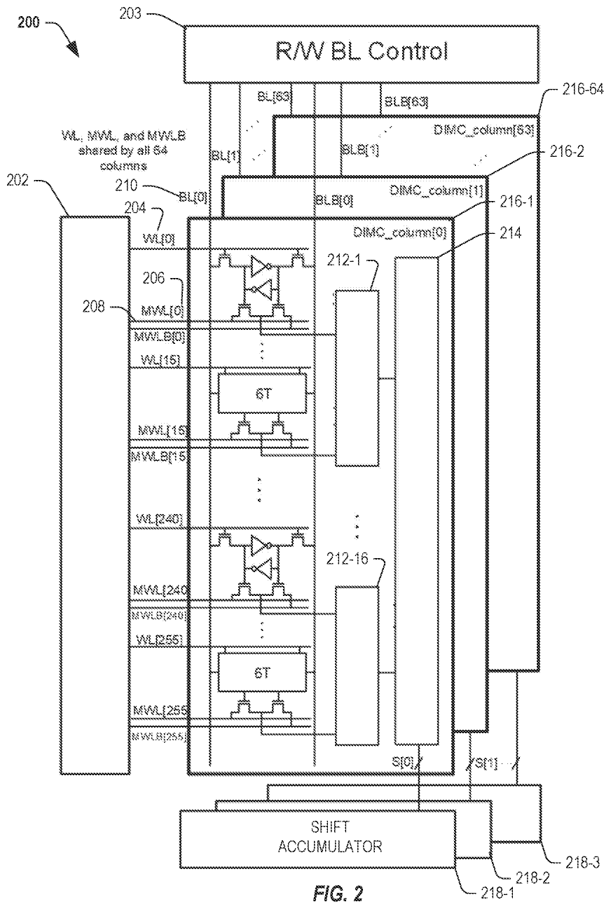

FIG. 2 shows the architecture of the DIMC-D macro circuit 200 integrating 256×64 bitcells according to the present disclosure. (DIMC-S has the same architecture except having 4-b CPRS signals.) A 16 k binary weight matrix can be stored in the macro, and by providing 256 bit-serial input activations from the left side of the macro, a binary vector-matrix dot-product can be performed in one cycle. Each of the 64 256-bit cell columns (e.g., 216-1, 216-2 to 216-64) of the macro integrates 256 binary multiply cells via wordline driver 202 and wordlines 204 and bitline controller 203 and bitlines 210, 16 approximate compressors 212-1 to 212-16, one 16-input adder tree 214, and one 11-bit shift accumulator 218. The wordlines 204 are shared by all 64 columns 216. The 16 compressors 212-1 to 212-16 count the number of l's in the results of the 256 binary multiplications (MBL [0:255]) and generate 3-b results (CPRS [0:2]). The adder tree 214 sums up the outputs of the compressors. Finally, the shift accumulator 218-1 accumulates the partial sum of each cycle in a pipelined manner if input activations are bit-serial multi-bit values. It is to be appreciated that for each of the 64 columns 216, a respective group of 16 compressors 212 is provided, respective adder trees 214, and respective shift accumulators 218.

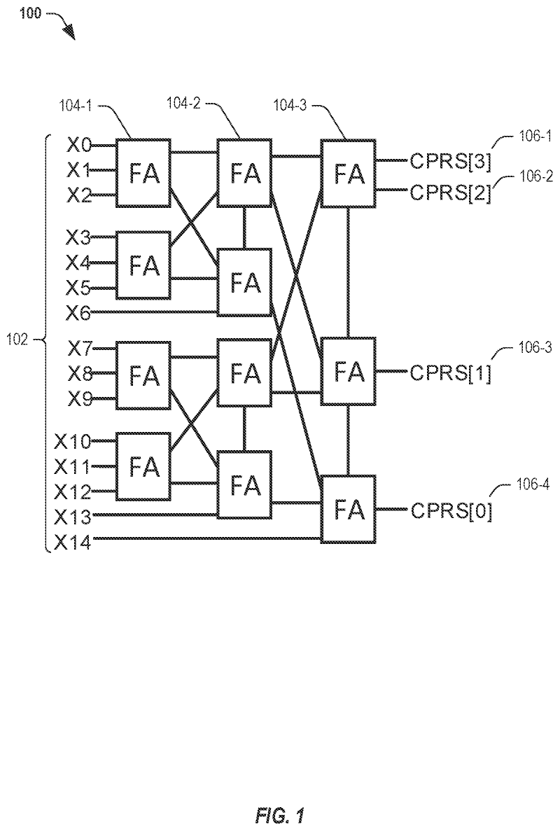

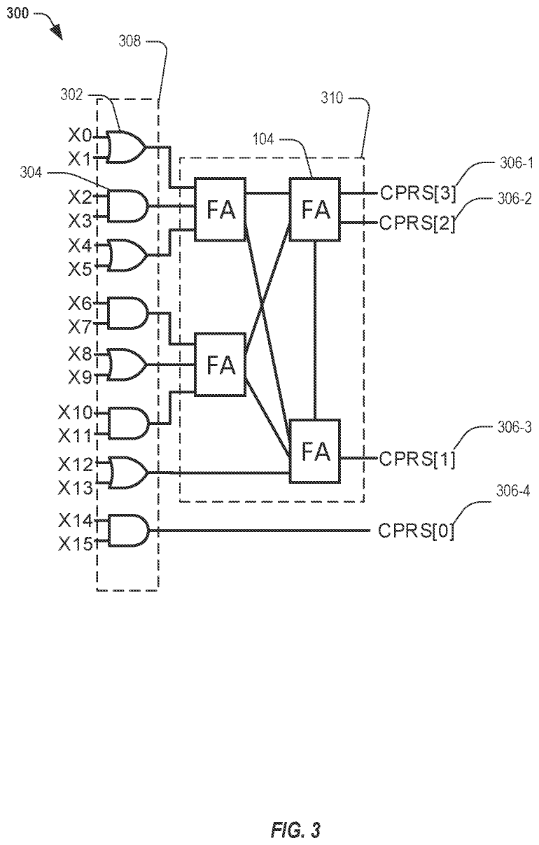

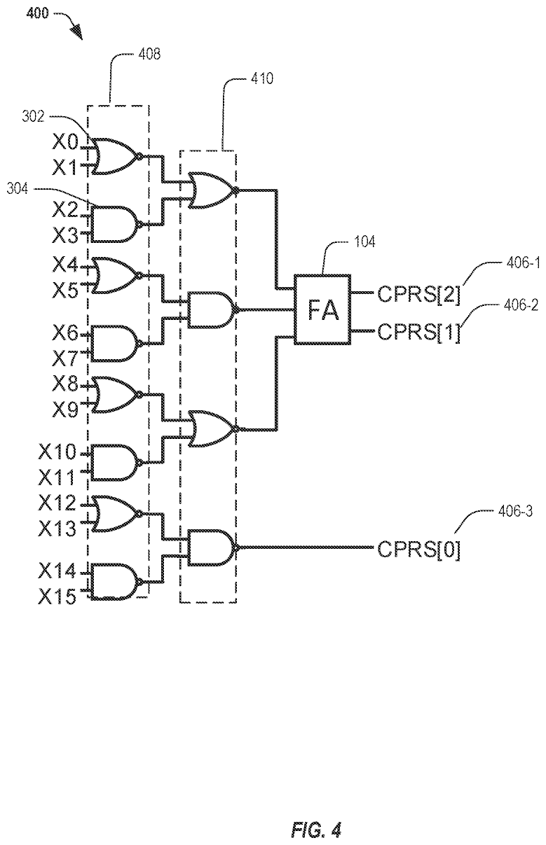

To improve the area efficiency of digital arithmetic hardware, the compressors 212 and FA circuits in the adder tree 214 are optimized. Three compressor circuits were designed: exact (shown in FIG. 1), single-approximate compressor 300 in FIG. 3, and double-approximate compressor 400 in FIG. 4. The approximate compressors use interleaved AND gates 304 and OR gates 302 to replace FAs 104. While an AND gate 304 can potentially cause −1 and an OR gate 302 can cause +1 error, some of those errors can cancel each other out. The double-approximate compressor 400 requires 55% fewer transistors than the exact counterpart in FIG. 1 and the single approximate compressor 300 requires 40% fewer transistors than the exact counterpart in FIG. 1, yet the double approximate compressor 400 exhibits a root mean square error of 6.76% over PVT variations while the single approximate compressor 300 exhibits a RMSE of 4.03%. The worst-case RMSE of DIMC is smaller than that of AMS hardware (22.5%), but the RMSE must be addressed for improving a CNN accuracy.

In the single approximate compressor 300, a plurality 308 of AND and OR logic gates receive as input respective pairs of bitcell values, and passes the output to a plurality 310 of FA circuits 104 to produce the 4-b CPRS signal.

In the double approximate compressor 400 first plurality 408 of AND and OR logic gates 394 and 302 that receive as input respective pairs of bitcell values, a second plurality 410 of AND and OR logic gates 304 and 302 that receive outputs of the first plurality 408 of AND and OR logic gates and the single approximate compressor also comprises a single full adder circuit 104 that receive outputs of the second plurality of AND and OR logic gates to produce the 3-b CPRS signal.

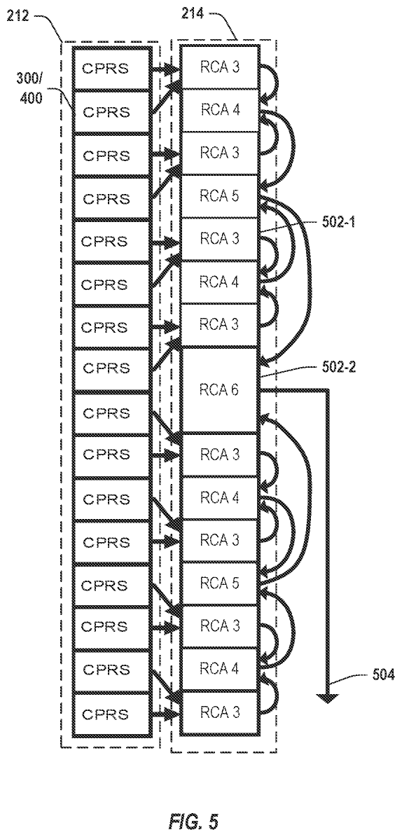

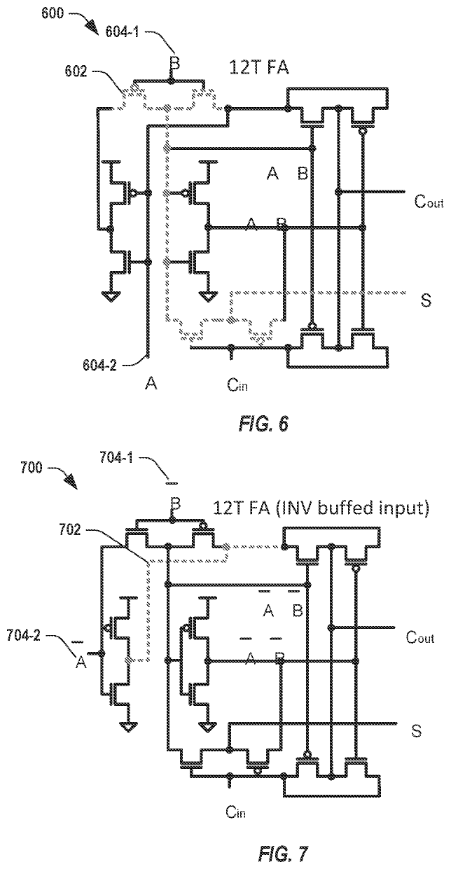

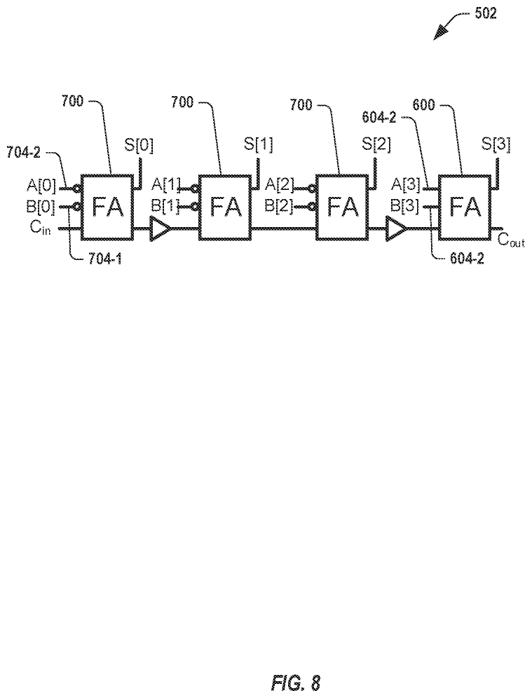

Also, a custom 12T (transistor) FA was designed and uses pass-gate logic (FIGS. 6 and 7 depict two different types of the custom FA) and a ripple-carry-adder (RCA) 214 based on those FAs is shown in FIG. 5.

In FIG. 5, a ripple carry adder tree 214 is shown according to one or more embodiments of the present disclosure. The RCA tree 214 comprises a plurality of RCAs (e.g., 502-1, 502-02, etc.) that are each themselves comprised of varying numbers of the custom 12T FAs shown in FIGS. 6 and 7. In an embodiment, the RCAs 502 can include 3, 4, 5, or 6 FA circuits. The RCAs 502 can receive the outputs of the compressors 212 (that are either single approximate compressor 300 or double approximate compressor 400) and can add the inputs using ripple carry logic to produce an output 504 that is provided to the shift accumulator 218.

FIGS. 6 and 7 illustrate the first and second types of custom full adder circuits 600 and 700 using pass-gate logic according to one or more embodiments of the present disclosure. The pass-gate logic has the well-known Vt drop problem. Therefore, all nodes in a FA 600 were identified that do not have full-swing signals (dashed line 602 in FIG. 6). Then, inverters were inserted to ensure that the number of series-connected pass-gates is less than two. Indeed, these added inverters modify the RCA logic, and to keep the logic correct, the second version of the 12T FA 700 was made (that has A_bar 704-2 and B_bar 704-1 as inputs instead of A 604-2 and B 604-1 as inputs in FA 600 (dashed line 702 in FIG. 7) and employed them accordingly in the RCA. The 12T FAs 600 and 700 consume 1.764 μm² (2250 F²).

FIG. 8 depicts an exemplary RCA 502 that has 4 FAs (including 3 FAs 700 and 1 FA 600). Different RCAs 502 can have different numbers and/or combinations of FAs 700 or 600.

Through the area optimizations, each 256-bitcell column (216-1 to 216-64) of DIMC-D having binary multipliers, compressors 212, adder tree 214, and shift-accumulator 218 uses 4336 transistors, marking the device efficiency of 16.94 T/b.

However, this highly optimized approximate arithmetic hardware would negatively affect CNN accuracy. The approximate hardware was benchmarked using a VGG-like 1b/1b weight/activation CNN model (128C3-128C3-P2-256C3-256C3-P2-512C3-512C3-P2-FC1024-FC1024-FC10, 128C3: 128 features 3×3 convolution, P2: 2×2 pooling, FC1024: 1024 fully connected) for CIFAR-10. Using the conventional training model, the version using double(single)-approximate hardware achieves a poor accuracy of 25.2% (50.9%), whereas the exact hardware achieves 89.6%. To compensate for the inaccuracy induced by the approximate hardware, an approximation-aware training algorithm was developed. In this algorithm, the forward path performs the vector-matrix multiplication by using a bitwise operation while considering approximate hardware. Gradient calculations are performed using full accuracy for training. The approximate hardware was then benchmarked for the newly trained VGG-like 1b/1b CNN model and CIFAR-10. The double-approximate version now can achieve higher accuracy of 86.9%, and the single-approximate version can achieve 89.0%, which is close to the exact hardware.

Interestingly, even with the approximation-aware training, the approximate hardware still results in lower accuracy for a multi-bit activation CNN model because multi-bit activation tends to require more accurate hardware. Specifically, multi-bit activation is often Gaussian distributed and thus MSBs are sparse and suffer from approximate errors. To improve the accuracy of a multi-bit activation CNN, number format is disclosed called multi-bit XNOR (MB-XNOR). Conventionally, in a 1b-weight neural network, each weight and activation represents +1 or −1 and XNOR fulfills bitwise multiplication. If the 2's complement format is used for activations, however, the binary weight also needs to be in 2's complement and can represent only −1 or 0. This results in large degradation to CNN accuracy. Therefore, the format of the binary weight was extended to represent an N-bit activation b_{N-1}b_{N-2} . . . b₀=Σᵢ bᵢ×2ᵢ, where bᵢ is +1 or −1. This format cannot represent 0, which disallows some of the activation functions such as rectified linear unit (ReLU). However, other popular activations can still be used, such as hyperbolic tangent (tanh) and leaky ReLU.

The MB-XNOR format according to the present disclosure has been confirmed to improve the accuracy of a multi-bit activation CNN model. The improvement was investigated both in signal-to-noise ratio (SNR) simulation and via CNN accuracy measurement. The SNR is formulated as SNR=Σy²ₜᵣᵤₑ/Σ(yₜᵣᵤₑ−yₐₚₚᵣₒₓ)², where yₜᵣᵤₑ is the ground truth of the dot-product between a 256-d Gaussian-distributed input vector quantized to 1-4 bits and a 256-d binomial-distributed weight vector, and where yₐₚₚᵣₒₓ is the same dot-product but is computed with approximate hardware. The DIMC-D macro with the 4-b input activations in the MB-XNOR format yields a 0.15 higher SNR than 2's complement. The CNN accuracy measurement confirms the same improvement: DIMC-S using the MB-XNOR successfully increases the CNN accuracy by 5.4%. Despite that DIMC-D also benefits from the MB-XNOR format, the accuracy with multi-bit activations is still lower than that with binary activations, making DIMC-D suitable for only a 1b/1b weight/activation CNN model.

A prototype of the DIMC test chip in 28 nm was developed. The 16 kb DIMC-D (DIMC-S) takes 0.033 mm² (0.049 mm²), marking the area efficiency of 2569 F²/b (3814 F²/b). The macros were measured at 0.5 V to 1.1 V at 25° C. DIMC-D achieves 932-2219 TOPS/W and 475-20032 GOPS; DIMC-S achieved 458-990 TOPS/W and 405-19215 GOPS (normalized to 1b/1b for comparison. The energy efficiency and throughput also were measured across five chips at the nominal voltage 0.9 V, the energy efficiency across the supply voltage was measured at 25%, and the input toggle rate was measured at 50%. The SRAM mode takes 340 ns (256 cycles at 752 MHz) to update in total 16 kb weights at 0.9 V. The DIMC macros according to the present disclosure achieve the best area efficiency while maintaining the-state-of-the-art throughput, energy efficiency, and CNN accuracy.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A digital in-memory computing macro circuit, comprising:
a plurality of approximate compressors wherein each approximate compressor of the plurality of approximate compressors receives as an input a plurality of bitcell values of a plurality of bitcell multiplications and generates an output comprising an approximate sum of the plurality of bitcell values;
an adder tree that receives a plurality of approximate sums, the plurality of approximate sums comprising an approximate sum from each approximate compressor of the plurality of approximate compressors and generates a sum corresponding to a total value of the plurality of bitcell multiplications, wherein the adder tree comprises a plurality of ripple carry adders that each comprise a plurality of full adder circuits that use inverters such that a number of series-connected pass-gates in each full adder circuit of the plurality of full adder circuits is less than two; and
a shift accumulator that accumulates the sum and sums of subsequent bitcell multiplication cycles in a pipeline.

2. The digital in-memory computing macro circuit of claim 1, wherein each approximate compressor is at least one of a single approximate compressor or a double approximate compressor.

3. The digital in-memory computing macro circuit of claim 2, wherein the approximate compressor is a single approximate compressor that comprises a plurality of AND and OR logic gates that receive as input respective pairs of bitcell values, and the single approximate compressor also comprises a plurality of full adders circuits that receive outputs of the plurality of AND and OR logic gates.

4. The digital in-memory computing macro circuit of claim 2, wherein the approximate compressor is a double approximate compressor that comprises a first plurality of AND and OR logic gates that receive as input respective pairs of bitcell values, a second plurality of AND and OR logic gates that receive outputs of the first plurality of AND and OR logic gates and the single approximate compressor also comprises a single full adder circuits that receive outputs of the second plurality of AND and OR logic gates.

5. The digital in-memory computing macro circuit of claim 2, wherein the double approximate compressor has fewer transistors than the single approximate compressor, and each of the single approximate compressor and the double approximate compressor have fewer transistors than an exact compressor.

6. The digital in-memory computing macro circuit of claim 2, wherein the single approximate compressor comprises less than 100 transistors.

7. The digital in-memory computing macro circuit of claim 2, wherein the double approximate compressor comprises less than 70 transistors.

8. The digital in-memory computing macro circuit of claim 1, wherein the ripple carry adders comprise at least one of three, four, five, or six full adder circuits.

9. The digital in-memory computing macro circuit of claim 1, wherein the full adder circuits of the ripple carry adders comprise one or more of each of a first type of full adder circuit and a second type of full adder circuit.

10. The digital in-memory computing macro circuit of claim 9, wherein the first type of full adder circuit and the second type of full adder circuit comprise inverters at every node in the full adder circuits that do not have a full-swing signal.

11. The digital in-memory computing macro circuit of claim 9, wherein the first type of full adder circuit corrects for a ripple carry adder logic modification caused by the second type of full adder circuit.

12. A digital in-memory computing macro circuit, comprising:
a plurality of single approximate compressors wherein each single approximate compressor of the plurality of approximate compressors receives as an input a plurality of bitcell values of a plurality of bitcell multiplications and generates an output comprising an approximate sum of the plurality of bitcell values;
an adder tree that receives a plurality of approximate sums, the plurality of approximate sums comprising an approximate sum from each single approximate compressor of the plurality of single approximate compressors and generates a sum corresponding to a total value of the plurality of bitcell multiplications, wherein the adder tree comprises a plurality of ripple carry adders that each comprise a plurality of full adder circuits that use inverters such that the number of series-connected pass-gates is less than two; and
a shift accumulator that accumulates the sum and sums of subsequent bitcell multiplication cycles in a pipeline.

13. The digital in-memory computing macro circuit of claim 12, wherein the single approximate compressor comprises a plurality of AND and OR logic gates that receive as input respective pairs of bitcell values, and the single approximate compressor also comprises a plurality of full adders circuits that receive outputs of the plurality of AND and OR logic gates.

14. The digital in-memory computing macro circuit of claim 12, wherein the approximate sum has a root mean square error of 4.03%.

15. The digital in-memory computing macro circuit of claim 12, wherein the single approximate compressor comprises less than 100 transistors.

16. The digital in-memory computing macro circuit of claim 12, wherein the full adder circuits of the ripple carry adders comprise one or more of each of a first type of full adder circuit and a second type of full adder circuit, wherein the first type of full adder circuit corrects for a ripple carry adder logic modification caused by the second type of full adder circuit.

17. A digital in-memory computing macro circuit, comprising:
a plurality of double approximate compressors wherein each double approximate compressor of the plurality of double approximate compressors receives as an input a plurality of bitcell values of a plurality of bitcell multiplications and generates an output comprising an approximate sum of the plurality of bitcell values;
an adder tree that receives a plurality of approximate sums, the plurality of approximate sums comprising an approximate sum from each double approximate compressor of the plurality of double approximate compressors and generates a sum corresponding to a total value of the plurality of bitcell multiplications, wherein the adder tree comprises a plurality of ripple carry adders that each comprise a plurality of full adder circuits that use inverters such that the number of series-connected pass-gates is less than two; and
a shift accumulator that accumulates the sum and sums of subsequent bitcell multiplication cycles in a pipeline.

18. The digital in-memory computing macro circuit of claim 17, wherein the double approximate compressor comprises a first plurality of AND and OR logic gates that receive as input respective pairs of bitcell values, a second plurality of AND and OR logic gates that receive outputs of the first plurality of AND and OR logic gates and the double approximate compressor also comprises a single full adder circuits that receive outputs of the second plurality of AND and OR logic gates.

19. The digital in-memory computing macro circuit of claim 17, wherein the approximate sum has a root mean square error of 6.76%.

20. The digital in-memory computing macro circuit of claim 17, wherein the full adder circuits of the ripple carry adders comprise one or more of each of a first type of full adder circuit and a second type of full adder circuit, wherein the first type of full adder circuit corrects for a ripple carry adder logic modification caused by the second type of full adder circuit.
